(19) United States
(12) Patent Application Publication
(10) Pub. No.: US 2024/0385240 A1
(43) Pub. Date: Nov. 21, 2024

(54) VERIFICATION METHOD AND VERIFICATION DEVICE

(71) Applicant: Realtek Semiconductor Corporation, Hsinchu (TW)

(72) Inventors: Xianghua SHEN, Jiangsu Province (CN); Zhenni WANG, Jiangsu Province (CN); Yanmei FENG, Jiangsu Province (CN); Zichen WANG, Jiangsu Province (CN)

(21) Appl. No.: 18/657,732

(22) Filed: May 7, 2024

(30) Foreign Application Priority Data
May 17, 2023 (CN) 202310558957.7

(51) Int. Cl. G01R 31/317

(52) U.S. Cl. CPC G01R 31/31718

(57) ABSTRACT

A verification method is disclosed. The verification method is applicable for a verification device, and the verification device is configured to verify a device under test. The device under test includes several functional blocks. The verification method includes the following operations: generating several test cases corresponding to the several functional blocks, in which the several test cases include a tree structure, in which every one of the several test cases inherits another one of the several test cases; and verifying the several functional blocks according to the several test cases and the tree structure.

### CROSS-REFERENCE TO RELATED APPLICATION

This application claims the priority benefit of CHINA Application serial no. 202310558957.7, filed May 17, 2023, the full disclosure of which is incorporated herein by reference.

### FIELD OF INVENTION

The present application relates to a verification method and a verification device. More particularly, the present application relates to a verification method and a verification device of a standardized methodology, such as the Universal Verification Methodology (UVM).

### BACKGROUND

With the progress of the integrated circuit manufacturing process and the increasing market demand for highly integrated products, the integration and complexity of the chip are getting higher and higher, and higher requirements are put forward for the verification of the chip. In order to be able to truly simulate the working scene of the chip, it is necessary to build a verification platform that further improves the scene and enriches the test cases.

In the chip verification process, the test cases are extremely important. For completing the functional verification of the chip, enough test cases for verification are in need. Different incentives will be placed in these test cases. Only the more incentives, the more comprehensive the verification is, and the verification of the chip will be more perfect. Meanwhile, improving the reusability of the test cases can speed up the verification, shorten the chip development cycle, and reduce the time for the chip to be introduced into the market, which is conducive to the repeated computing development of the chip. Currently, UVM-based verification has not proposed a method for building a mix multiplexing test case. Therefore, how to efficiently mix and reuse the test cases is one of the problems to be solved in this field.

### SUMMARY

The disclosure provides a verification method. The verification method is applicable for a verification device, and the verification device is configured to verify a device under test. The device under test includes several functional blocks. The verification method includes the following operations: generating several test cases corresponding to the several functional blocks, in which the several test cases include a tree structure, in which every one of the several test cases inherits another one of the several test cases; and verifying the several functional blocks according to the several test cases and the tree structure.

The disclosure provides a verification device. The verification device is applicable for verifying a device under test, in which the device under test includes several functional blocks. The verification device includes a test case generating circuit and a testing circuit. The test case generating circuit is configured to generate several test cases corresponding to the several functional blocks, and is configured to create a tree structure of the several test cases, in which every one of the several test cases inherits another one of the several test cases. The testing circuit is connected to the test case generating circuit, and the testing circuit is configured to verify the several functional blocks according to the several test cases and the tree structure.

It is to be understood that both the foregoing general description and the following detailed description are by examples and are intended to provide further explanation of the invention as claimed.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is a schematic diagram illustrating a verification device according to some embodiments of the present disclosure.

FIG. 2 is a flow chart diagram illustrating a verification method according to some embodiments of the present disclosure.

FIG. 3 is a schematic diagram illustrating a tree structure of test cases according to some embodiments of the present disclosure.

FIG. 4 is a schematic diagram illustrating a tree structure of test cases according to some embodiments of the present disclosure.

FIG. 5 is a schematic diagram illustrating a tree structure of test cases according to some embodiments of the present disclosure.

FIG. 6 is a schematic diagram illustrating a tree structure of test cases according to some embodiments of the present disclosure.

FIG. 7 is a schematic diagram illustrating a tree structure of test cases according to some embodiments of the present disclosure.

FIG. 8 is a schematic diagram illustrating test case configuration file according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. The term “coupled” used herein may also refer to “electrically coupled”, and the term “connected” may also refer to “electrically connected”. “Coupled” and “connected” may also refer to Refers to two or several elements that cooperate or interact with each other.

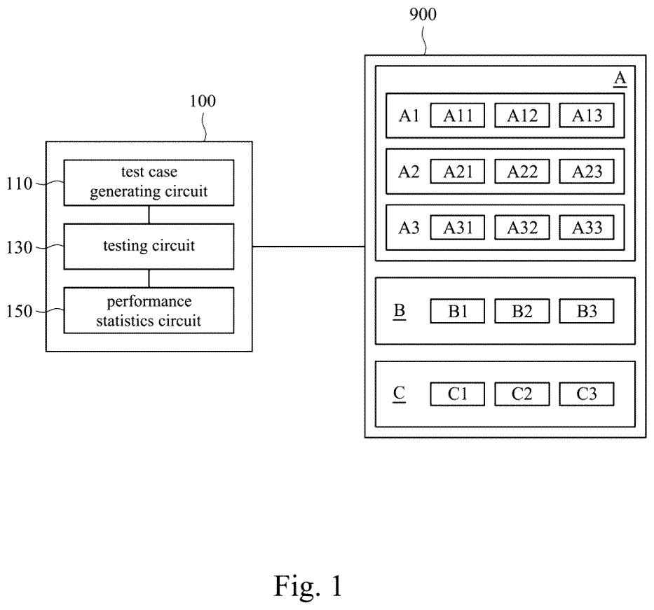

Reference is made to FIG. 1. FIG. 1 is a schematic diagram illustrating a verification device 100 according to some embodiments of the present disclosure. As illustrated in FIG. 1, the verification device 100 is coupled to the device under test (Device Under Test, DUT) 900. In detail, the verification device 100 includes a test case generating circuit 110 and a testing circuit 130. In the connection relationship, the test case generating circuit 110 is connected to the testing circuit 130. The testing circuit 130 is coupled to the device under test 900.

As illustrated in FIG. 1, in some embodiments, the verification device 100 further includes a performance statistics circuit 150. The performance statistics circuit 150 is connected to the testing circuit 130. The performance statistics circuit 150 is coupled to the device under test 900.

The verification device 100 as illustrated in FIG. 1 is only for illustrative purposes only, and the embodiments of the present disclosure are not limited thereto.

In some embodiments, the device under test 900 includes several functional blocks A, B, C. The functional block A further includes several functional blocks A1, A2, A3. The functional block A1 includes functional blocks A11, A12, A13. The functional block A2 includes functional blocks A21, A22, A23. The functional block A3 includes functional blocks A31, A32, A33. The functional block B further includes several functional blocks B1, B2, B3. The functional block C further includes several functional blocks C1, C2, C3.

In some embodiments, the functional blocks A1, A2, A3 are son functional blocks of the functional block A, the functional blocks A11, A12, A13 are son functional blocks of the functional block A1, and so on. On the other hand, the functional block A is a father functional block of the functional blocks A1, A2, A3, the functional block A1 is a father functional block of the functional blocks A11, A12, A13, and so on.

The above-mentioned functional blocks are for illustrative purposes only, and more functional blocks may be included. In addition, the functional block A11 may also include several functional blocks, and so on.

In some embodiments, the functional blocks as mentioned above can be realized by the functional circuits.

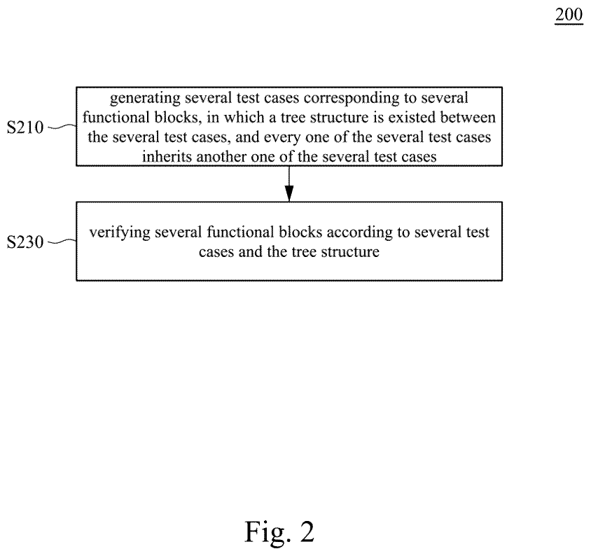

The detailed operation method of the verification device 100 in FIG. 1 will be described with reference to FIG. 2 below.

Reference is made to FIG. 2. FIG. 2 is a flow chart diagram illustrating a verification method 200 according to some embodiments of the present disclosure. The verification method 200 can be applied to the verification device 100 as illustrated in FIG. 1. The verification method 200 includes operations S210 to S230.

In operation S210, several test cases corresponding to several functional blocks are generated, in which a tree structure is existed between the several test cases, and every one of the several test cases inherits another one of the several test cases. In some embodiments, the operation S210 is performed by the test case generating circuit 110 as illustrated in FIG. 1.

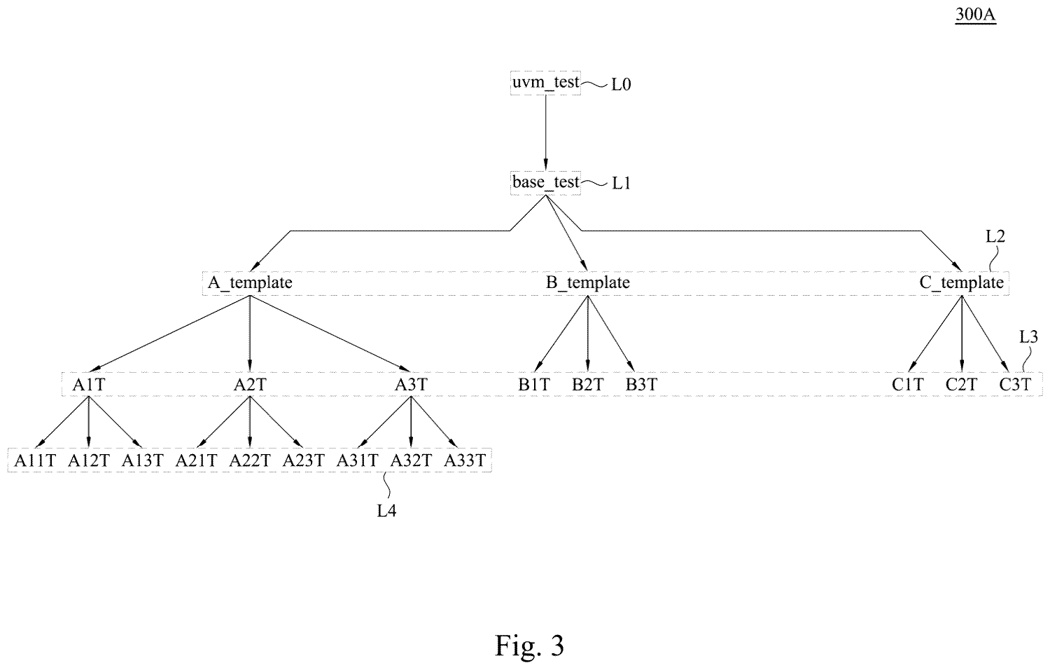

Reference is made to FIG. 3 together. FIG. 3 is a schematic diagram illustrating a tree structure 300A of test cases according to some embodiments of the present disclosure. As illustrated in FIG. 3, several test cases uvm_test, base_test, A_template, B_template, C_template, A1T, A2T, A3T, B1T, B2T, B3T, C1T, C2T, C3T, A11T, A12T, A13T, A21T, A22T, A23T, A31T, A32T, A33T includes a tree structure relationship between each other.

Reference is made to FIG. 1 together. There is a one-to-one correspondence between several test cases illustrated in FIG. 3 and several functional blocks illustrated in FIG. 1. For example, the test case A_template corresponds to the functional block A, the test case B_template corresponds to the functional block B, the test case C_template corresponds to the functional block C. The test case A1T corresponds to the functional block A1, the test case A2T corresponds to the functional block A2, and so on.

As illustrated in FIG. 3, several functional test cases include several hierarchical levels. For example, the test case uvm_test is located at the hierarchical level L0, the test case base_test is located at the hierarchical level L1, the test cases A_template, B_template, C_template are located at the hierarchical level L2, the test cases A1T, A2T, A3T, B1T, B2T, B3T, C1T, C2T, C3T are located at the hierarchical level L3, the test cases A11T, A12T, A13T, A21T, A22T, A23T, A31T, A32T, A33T are located at the hierarchical level L4.

The structure as illustrated in FIG. 3, the test case uvm_test is a test case of the hierarchical level L0, the test case base_test is a test case of the hierarchical level L1, the test cases A_template, B_template, C_template are the test case of the hierarchical level L2, the test cases A1T, A2T, A3T, B1T, B2T, B3T, C1T, C2T, C3T are the test case of the hierarchical level L3, the test cases A11T, A12T, A13T, A21T, A22T, A23T, A31T, A32T, A33T are test case of the hierarchical level L4.

The arrows drawn in FIG. 3 represent the inheritance relations between test cases. In some embodiments, for example, using the inheritance feature of System Verilog language, each test case inherits one of the test cases of the previous hierarchical level. For example, the test case base_test inherits the test case uvm_test. The test case A_template, B_template, and C_template inherit the test case base_test. The test cases A1T, A2T, A3T inherit the test case A_template, the test cases B1T, B2T, B3T inherit the test case B_template, and the test cases C1T, C2T, C3T inherit the test case C_template. The test cases A11T, A12T, A13T inherit the test case A1T. The test cases A21T, A22T, A23T inherit the test case A2T. The test cases A31T, A32T, A33T inherit the test case A3T.

In some embodiments, the test case includes the inherited test case. For example, the test case A1T inherits the test case A_template, and the test case A1T includes the test case A_template, and so on.

In some embodiments, the inherited test case further includes the several second libraries, in which the several second libraries are generated according to the several first libraries of the inherited test cases, and the second libraries replace the first libraries. For example, the test case AT inherits the test case A_template, and the test case A1T generates the libraries of the several test case A1T according to the several libraries of the test case A_template, and so on.

In detail, the test case A1T adds triggering conditions or related verify content and conditions corresponding to the functional block A1 of FIG. 1 on the basis of the libraries of the test case A_template to generate test case A1T libraries. In some embodiments, the test case A1T further replaces several libraries of test case A_template with the libraries of test case A1T in test case A1T. The above libraries are replaced by the implementation of UVM's factory override.

In some embodiments, the father-son relationship between the two test cases includes the inheritance relation. For example, the test case A1T inherits the test case A_template, and the test case A1T is the son test case of the test case A_template, and the test case A_template is the father test case of the test case A1T.

In some embodiments, the test case that does not inherit other test cases is the root test case. For example, in the tree structure 300A, the test case uvm_test is the root test case.

In some embodiments, with a test case as the starting node, all test cases inherited the starting node or other test cases that indirectly inherit from the starting node's test case are the offspring test cases whose starting nodes are other test cases. For example, if the test case A_template is used as the starting node, the test cases A1T, A2T, A3T inheriting the test case A_template and the test cases A11T, A12T, A13T, A21T, A22T, A23T, A31T, A32T, A33T, which inherit the test case A_template through the test cases A1T, A2T, A3T, are the offspring test case of the test case A_template.

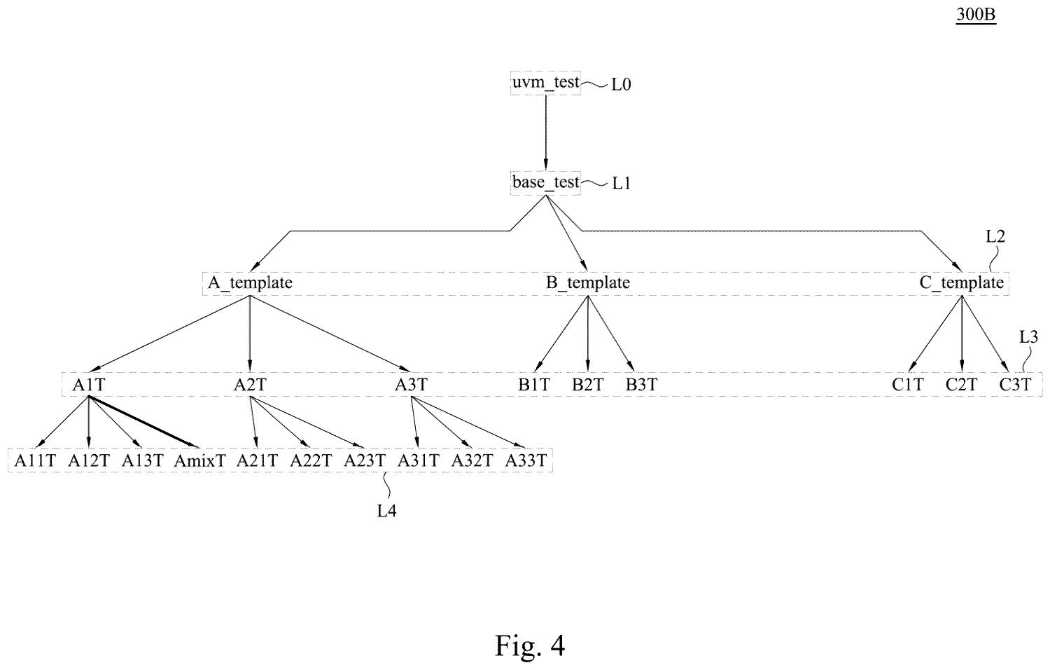

Reference is made to FIG. 4. FIG. 4 is a schematic diagram illustrating a tree structure 300B of test cases according to some embodiments of the present disclosure. FIG. 4 illustrates an example of performing mix verification of two test cases inherited from the same test case (that is, a mix verification inside a single functional block). For example, when test case A11T and test case A12T are to be mixed and verified, the test case generating circuit 110 is further configured to generate the test case AmixT, and to assign the test case AmixT to inherit the test case A1T, that is, to make test case AmixT becomes the son test case of the test case A1T. The test case AmixT is a mix test case, and the test case AmixT is configured to mix verify the test case A11T, the test case A12T and the test case A13T.

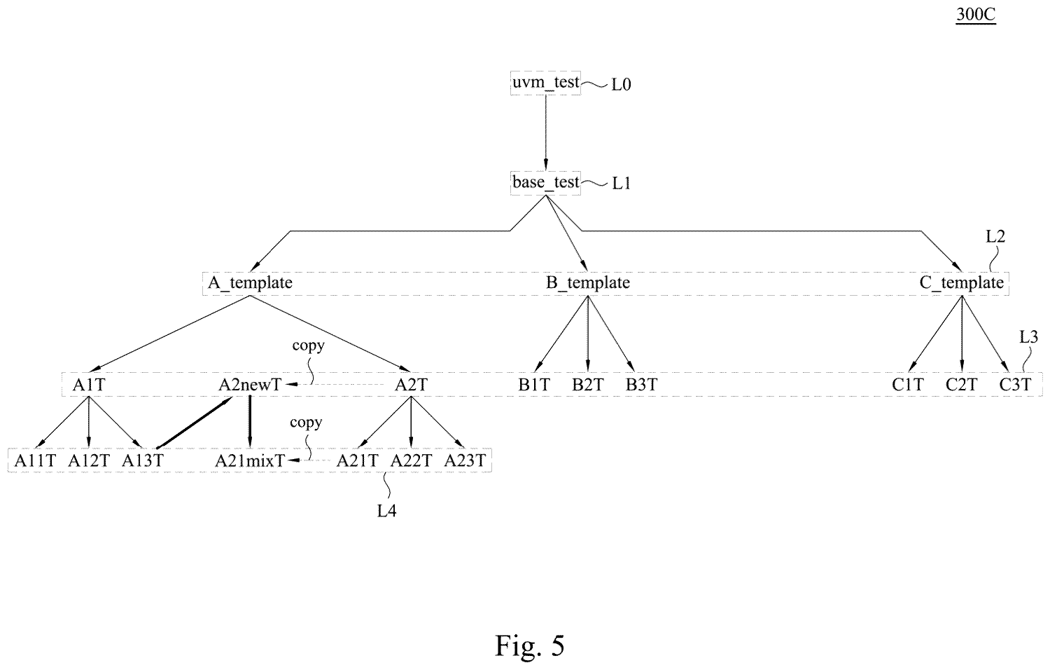

Reference is made to FIG. 5. FIG. 5 is a schematic diagram illustrating a tree structure 300C of test cases according to some embodiments of the present disclosure. FIG. 5 illustrates an example of performing mix verification two test cases that are inherited from different test cases but not at the same hierarchical level (that is, a cross-functional block mix test). For example, reference is made to FIG. 3 again. The test case A13T and the test case A21T are test cases of the same hierarchical level but inherit different test cases of the previous hierarchical level. In detail, both of the test cases A13T and A21T are test cases of the hierarchical level L4. The test case A13T inherits the test case A1T of the hierarchical level L3, and the test case A21T inherits the test case A2T of the hierarchical level L3.

Reference is made to FIG. 5 again. When mixing verifying the test case A13T and the test case A21T, the test case generating circuit 110 is further configured to copy the test case A2T to generate the sub test case A2newT, and to copy the test case A21T to generate the mix test case A21mixT. Next, the test case generating circuit 110 is further configured to assign the mix test case A21mixT to inherit the sub test case A2newT, and to assign the sub test case A2newT to inherit the test case A13T. The test case A21mixT is a mix test case, and the test case A21mixT is configured to mix verify the test case A13T and the test case A21T.

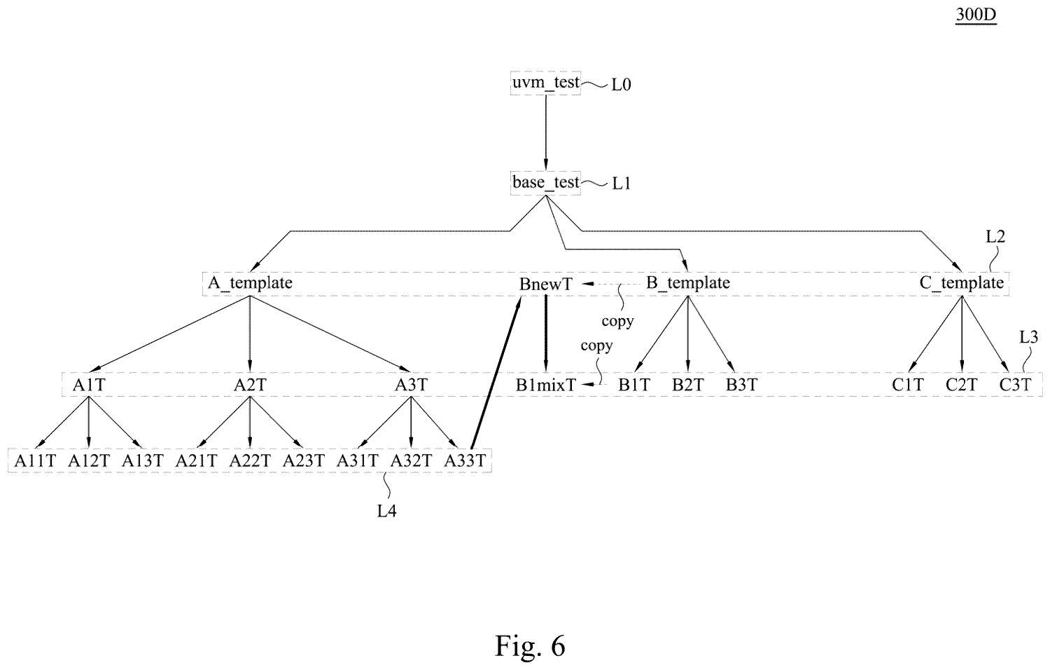

Reference is made to FIG. 6. FIG. 6 is a schematic diagram illustrating a tree structure 300D of test cases according to some embodiments of the present disclosure. FIG. 6 illustrates an example of performing mix verification on two test cases that are inherited from different test cases and are located at different hierarchical levels (that is, a mix verification that crosses functional blocks and crosses hierarchical levels). For example, reference is made to FIG. 3. The test case A33T and the test case B1T are test cases of different hierarchical levels and inherit different test cases. In detail, the test case A33T is a test case of the hierarchical level L4, and the test case B1T is a test case of the hierarchical level L3. The test case A33T inherits the test case A3T of the hierarchical level L3, and the test case B1T inherits the test case B_template of the hierarchical level L2.

Reference is made to FIG. 6 again. When mix verifying the test case A33T and the test case B1T, the test case generating circuit 110 is further configured to copy the test case B_template to generate the sub test case BnewT, and to copy the test case B1T to generate the mix test case B1mixT. Then, the test case generating circuit 110 is further configured to assign the mix test case B1mixT to inherit the sub test case BnewT, and to assign the sub test case BnewT to inherit the test case A33T. The test case B1mixT is a mix test case, and the test case B1mixT is configured to mix verify the test case A33T and the test case B1T.

The situation as illustrated in FIG. 6. The test case A33T is an offspring test case of the test case A_template, and the test case B1T is an offspring test case of the test case B_template. The test case A_template and the test case B_template inherits the same test case, which is the test case base_test located at the hierarchical level L1. Since the depth of the test case B1T is smaller than the depth of the test case A33T, the test case generating circuit 110 copies the test case B1T and all of the ancestor test cases trackback from the test case B1T to the test case B_template, to generate several sub ancestor test cases. For example, in the situation of FIG. 6, the test case B_template is the ancestor test case of the test case B1T. That is, the test case generating circuit 110 copies the test case B1T to generate the mix test case B1mixT, and the test case generating circuit 110 copies the test case B_template to generate the sub ancestor test case BnewT.

The above-mentioned depth is the hierarchical level of the test case. A test case with fewer hierarchical levels has a smaller depth. Conversely, a test case with more hierarchical levels has a larger depth.

Then, the test case generating circuit 110 create the inheritance relations between the sub ancestor test case BnewT and the mix test case B1mixT according to inheritance relations tracing back from the test case B1T to the test case B_template. In detail, since the test case B1T inherits the test case B_template, the test case generating circuit 110 assigns the mix test case B1mixT to inherit the sub ancestor test case BnewT according to the above-mentioned inheritance relation.

The sub ancestor test case BnewT is an ancestor test case (and a father test case) of the mix test case B1mixT. Since the sub ancestor test case BnewT does not inherit any test case of the previous hierarchical level, the sub ancestor test case BnewT is a root test case of the ancestor test case of the mix test case B1mixT. The test case generating circuit 110 is further configured to assign the sub ancestor test case BnewT to inherit the test case A33T.

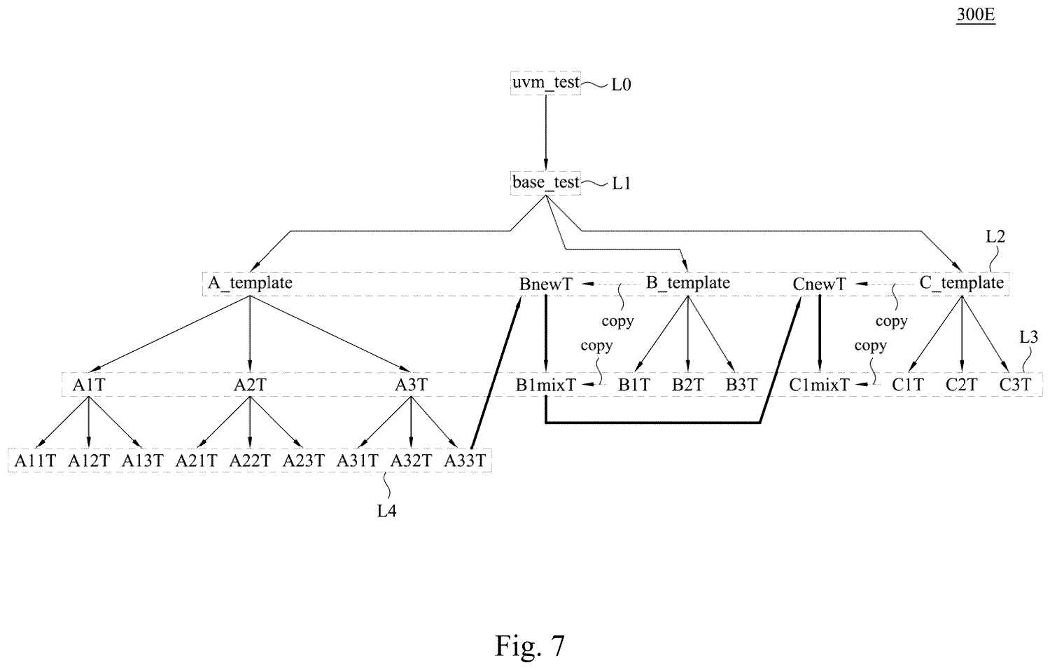

Reference is made to FIG. 7. FIG. 7 is a schematic diagram illustrating a tree structure 300E of test cases according to some embodiments of the present disclosure. FIG. 7 illustrates an example of mix verification among three test cases inheriting different test cases to carry out an example of mix verification (that is, the mix verification across functional blocks). For example, when mix verifying the test case A33T, the test case B1T and the test case C1T, the test case A33T is a test case of the hierarchical level L4, and the test case B1T and the test case C1T are test cases of the hierarchical level L3. The test case A33T inherits the test case A3T of the hierarchical level L3, the test case B1T inherits the test case B_template of the hierarchical level L2, and the test case C1T inherits the test case C_template of the hierarchical level L2.

Reference is made to FIG. 7 again. When mix verifying the test case A33T, the test case B1T and the test case C1T, the test case generating circuit 110 as illustrated in FIG. 1 first generates the mix test case B1mixT for mix verifying the test case A33T and test case B1T, then, the test case generating circuit 110 generates the mix test case C1mixT for mix verifying the test case A33T, the test case B1T and the test case C1T.

According to the test cases and tree structures as mentioned in the above FIG. 3 to FIG. 7, according to the tree structure of the test cases, only by copying the test cases and creating the inheritance relations between the test cases, the mix test cases are created to mix verify different functional blocks.

In detail, the test case generating circuit 110 as illustrated in FIG. 1 copies the test case B_template to generate the sub test case BnewT, and the test case generating circuit 110 copies the test case B1T to generate the mix test case B1mixT. Then, the test case generating circuit 110 is further configured to assign the mix test case B1mixT to inherit the sub test case BnewT, and to assign the sub test case BnewT to inherit the test case A33T.

Then, the test case generating circuit 110 copies the test case C_template to generate the sub test case CnewT, and the test case generating circuit 110 copies the test case C1T to generate the mix test case C1mixT. Then, the test case generating circuit 110 is further configured to assign the mix test case C1mixT to inherit the sub test case CnewT, and to assign the sub test case CnewT to inherit the test case B1mixT.

The generated test case C1mixT is a mix test case, and the test case C1mixT is configured to mix verify the test case A33T, the test case B1T and the test case C1T.

Reference is made to FIG. 2 again. In operation S230, several functional blocks are verified according to several test cases and the tree structure. In some embodiments, the operation S230 is operated by the testing circuit 130 and the performance statistics circuit 150 as illustrated in FIG. 1.

In some embodiments, testing circuit 130 as illustrated in FIG. 1 verifies the several functional blocks of the device under test 900 as illustrated in FIG. 1 according to the test cases and the tree structures as illustrated in the above FIG. 3 to FIG. 7.

In some embodiments, in operation S230, the performance statistics circuit 150 is further configured to calculate the mix triggering probability of the mix test case according to the triggering probabilities of the several functional blocks of the mix test case.

For example, reference is made to FIG. 1 and FIG. 7 together. The mix test case C1mixT as illustrated in FIG. 7 is configured to mix verifies the test case A33T, the test case B1T and the test case C1T. The test case A33T corresponds to the functional block A33 in FIG. 1, the test case B1T corresponds to the functional block B1 in FIG. 1, the test case C1T corresponds to the functional block C1 in FIG. 1. When verifying efficiency of the mix test case C1mixT, the performance statistics circuit 150 obtain the probability rate A33 of the functional block A33 being triggered, the probability rate B1 of the functional block B1 being triggered, and the probability rate C1 of the functional block C1 being triggered during the verification. Then, the performance statistics circuit 150 multiplied the probability rate A33 of the functional block A33 being triggered, the probability rate B1 of the functional block B1 being triggered, and the probability rate C1 of the functional block C1 being triggered, so as to obtain the efficiency rate C1mixT of the mix test case C1mixT.

That is, rateC1mixT=rateA33×rateB1×rateC1.

The performance statistics circuit 150 as described above ensures the practicality of the test case.

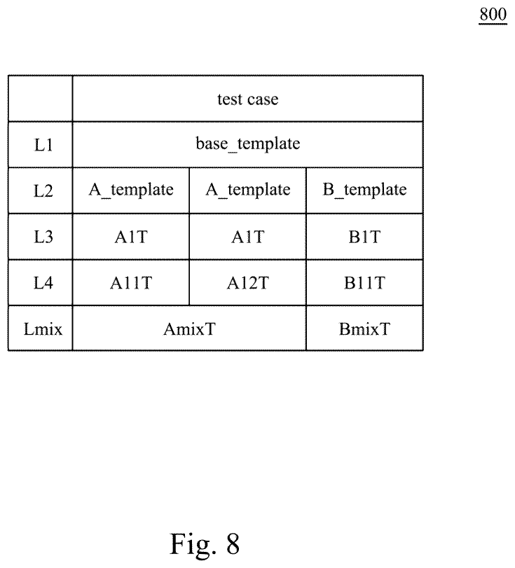

Reference is made to FIG. 8. FIG. 8 is a schematic diagram illustrating the test case configuration file 800 according to some embodiments of the present disclosure. In some embodiments, the test case generating circuit 110 as illustrated in FIG. 1 is further configured to generate the test cases and the tree structures as illustrated in the above mentioned FIG. 3 to FIG. 7 according to the test case configuration file 800. In some embodiments, the test case generating circuit 110 generates several test cases base_template, A_template, B_template, A1T, B1T, A11T, A12T, B11T, AmixT and BmixT according to the test case configuration file 800 as illustrated in FIG. 8. The test case base_template is a test case of the hierarchical level L1, the test cases A_template and B_template are test cases of the hierarchical level L2, the test cases A1T and B1T are test case of the hierarchical level L3, the test cases A11T, A12T and B11T are test case of the hierarchical level L4, and the test cases AmixT and BmixT are test cases of the mix test case Lmix.

In some embodiments, the test case generating circuit 110 inherits from top to bottom according to each column in the test case configuration file 800 as shown in FIG. 8. That is, the test cases A_template and B_template inherit the test case base_template, the test case A1T inherits the test case A_template, the test case B1T inherits the test case B_template, the test case A11T inherits the test case A1T, the test case A12T inherits the test case A1T, the test case B11T inherits the test case B1T, the test case AmixT inherits the test case A11T, in which all of the configurations of the test cases A11T and A12T, and the test case BmixT inherits the test case B11T.

Thus, in some embodiments, using the test case configuration file 800 shown in FIG. 8, the test case generating circuit 110 in FIG. 1 can automatically, quickly and accurately generate the test cases and the inheritance relations between the test cases.

In summary, the embodiments of the present disclosure provides a verification method and a verification device, based on the creation of the tree structure of the test cases, and based on the characteristics of UVM's factory replacement, whether to perform mix verification on different functional (son functional) in the same functional module in the chip, or to perform the mix verify among different functional modules in the chip, the verification can be realized only by copying test cases and creating the inheritance relations between the test cases, which reduces the difficulty of writing mix test case, reduces the writing time of test case, and improves the verification efficiency. In addition, the verification across functional modules can further effectively improve the coverage of chip verification. The above mentioned method can further improve the reusability of the test cases, so that the test case structures can be reused in the development of the chip, which improves the verification efficiency, and reduces the development time and cycle.

In addition, it should be noted that in the operations of the above mentioned signal transmission method, no particular sequence is required unless otherwise specified. Moreover, the operations may also be performed simultaneously or the execution times thereof may at least partially overlap.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A verification method, applicable for a verification device, configured to verify a device under test, wherein the device under test comprises a plurality of functional blocks, wherein the verification method comprises:
generating a plurality of test cases corresponding to the plurality of functional blocks, wherein the plurality of test cases comprise a tree structure, wherein every one of the plurality of test cases inherits another one of the plurality of test cases; and
verifying the plurality of functional blocks according to the plurality of test cases and the tree structure.

2. The verification method of claim 1, wherein the plurality of test cases comprise a first test case, a second test case and a third test case, and the third test case is a father test case of the first test case and the second test case, wherein the verification method further comprises:
generating a mix test case to mix verify the first test case and the second test case; and
assigning the mix test case to be a son test case of the third test case, and assigning the mix test case to inherit the third test case.

3. The verification method of claim 2, wherein the first test case corresponds to a first functional block of the plurality of functional blocks, the second test case correspond to a second functional block of the plurality of functional blocks, wherein the verification method further comprises:
calculating a mix triggering probability of the mix test case according to a first triggering probability of the first functional block and a second triggering probability of the second functional block.

4. The verification method of claim 1, wherein the plurality of test cases comprise a plurality of first hierarchical level test cases and a plurality of second hierarchical level test cases, wherein each of the plurality of second hierarchical level test cases inherits one of the plurality of first hierarchical level test cases.

5. The verification method of claim 4, wherein a first test case of the plurality of second hierarchical level test cases inherits a second test case of the plurality of first hierarchical level test cases, wherein the verification method further comprises:
generating a plurality of second libraries according to a plurality of first libraries of the second test case of the plurality of first hierarchical level test cases in the first test case of the plurality of second hierarchical level test cases, wherein the second test case of the plurality of first hierarchical level test cases is inherited by the first test case of the plurality of second hierarchical level test cases.

6. The verification method of claim 4, wherein the plurality of first hierarchical level test cases comprise a first test case, the plurality of second hierarchical level test cases comprise a second test case and a third test case, and both of the second test case and the third test case inherit the first test case, wherein the verification method further comprises:
generating a mix test case to mix verify the second test case and the third test case; and
assigning the mix test case to inherit the first test case.

7. The verification method of claim 4, wherein the plurality of first hierarchical level test cases comprise a first test case and a second test case, the plurality of second hierarchical level test cases comprise a third test case and a fourth test case, wherein the third test case inherits the first test case, and the fourth test case inherits the second test case, wherein the verification method further comprises:
copying the second test case to generate a sub second test case;
copying the fourth test case to generate a mix test case; and
assigning the mix test case to inherit the sub second test case, and assigning the sub second test case to inherit the third test case;
wherein the mix test case is configured to mix verify the third test case and the fourth test case.

8. The verification method of claim 4, wherein the plurality of first hierarchical level test cases comprise a first test case, the plurality of second hierarchical level test cases comprise a second test case and a third test case, and the first test case is a father test case of the second test case and the third test case, wherein a fourth test case of the plurality of test cases is an offspring test case of the second test case, and a fifth test case of the plurality of test cases is an offspring test case of the third test case, wherein the verification method further comprises:
copying the fourth test case to generate a first mix test case, wherein the first mix test case is configured to mix verify the fourth test case and the fifth test case;
copying a plurality of first ancestor test cases tracing back from the fourth test case to the second test case to generate a plurality of sub first ancestor test cases;
creating at least one second inheritance relation between the first mix test case and the plurality of sub first ancestor test cases according to at least one first inheritance relation tracing back from the fourth test case to the second test case; and
assigning a first root test case of the plurality of sub first ancestor test cases to inherit the fifth test case, wherein the first root test case is generated by copying the second test case.

9. The verification method of claim 8, wherein a first depth of the fourth test case is smaller than a second depth of the fifth test case.

10. The verification method of claim 8, wherein the plurality of second hierarchical level test cases further comprise a sixth test case, and the first test case is the father test case of the sixth test case, wherein a seventh test case of the plurality of test cases is an offspring test case of the sixth test case, wherein the verification method further comprises:
copying the seventh test case to generate a second mix test case, wherein the second mix test case is configured to mix verify the fourth test case, the fifth test case and the seventh test case;
copying a plurality of second ancestor test cases tracing back from the seventh test case to the sixth test case to generate a plurality of sub second ancestor test cases;
creating at least one fourth inheritance relation between the second mix test case and the plurality of sub second ancestor test case according to at least one third inheritance relation tracing back from the seventh test case to the sixth test case; and
assigning a second root test case of the plurality of sub second ancestor test cases to inherit the fifth test case, wherein the second root test case is generated by copying the sixth test case.

11. The verification method of claim 1, wherein the verification method further comprises:
generating the plurality of test cases and a plurality of inheritance relations between the plurality of test cases according to a test case configuration file.

12. A verification device, applicable for verifying a device under test, wherein the device under test comprises a plurality of functional blocks, wherein the verification device comprises:
a test case generating circuit, configured to generate a plurality of test cases corresponding to the plurality of functional blocks, and configured to create a tree structure of the plurality of test cases, wherein every one of the plurality of test cases inherits another one of the plurality of test cases; and
a testing circuit, connected to the test case generating circuit, configured to verify the plurality of functional blocks according to the plurality of test cases and the tree structure.

13. The verification device of claim 12, wherein the plurality of test cases comprise a plurality of first hierarchical level test cases and a plurality of second hierarchical level test cases, wherein each of the plurality of second hierarchical level test cases inherits one of the plurality of first hierarchical level test cases.

14. The verification device of claim 13, wherein the plurality of first hierarchical level test cases comprise a first test case, the plurality of second hierarchical level test cases comprise a second test case and a third test case, and both of the second test case and the third test case inherit the first test case, wherein the test case generating circuit is further configured to generate a mix test case to mix verify the second test case and the third test case, and is configured to assign the mix test case to inherit the first test case.

15. The verification device of claim 14, wherein the first test case correspond to a first functional block of the plurality of functional blocks, the second test case corresponds to a second functional block of the plurality of functional blocks, the verification device further comprises:
a performance statistics circuit, connected to the testing circuit, configured to calculate a mix triggering probability of the mix test case according to a first triggering probability of the first functional block and a second triggering probability of the second functional block.

16. The verification device of claim 13, wherein the plurality of first hierarchical level test cases comprise a first test case and a second test case, the plurality of second hierarchical level test cases comprise a third test case and a fourth test case, wherein the third test case inherit the first test case, and the fourth test case inherits the second test case, wherein the test case generating circuit is further configured to copy the second test case to generate a sub second test case, to copy the fourth test case to generate a mix test case, to assign the mix test case to inherit the sub second test case, and to assign the sub second test case to inherit the third test case, wherein the mix test case is configured to mix verify the third test case and the fourth test case.

17. The verification device of claim 13, wherein the plurality of first hierarchical level test cases comprise a first test case, the plurality of second hierarchical level test cases comprise a second test case and a third test case, and the first test case is a father test case of the second test case and the third test case, wherein a fourth test case of the plurality of test cases is an offspring test case of the second test case, and a fifth test case of the plurality of test cases is an offspring test case of the third test case, wherein the test case generating circuit is further configured to copy the fourth test case to generate a first mix test case, to copy a plurality of first ancestor test cases tracing back form the fourth test case to the second test case to generate a plurality of sub first ancestor test cases, to create at least one second inheritance relation between the first mix test case and the plurality of sub first ancestor test cases according to at least one first inheritance relation tracing back from the fourth test case to the second test case, and to assign a first root test case of the plurality of sub first ancestor test cases to inherit the fifth test case, wherein the first root test case is generated by copying the second test case, wherein the first mix test case is configured to mix verify the fourth test case and the fifth test case.

18. The verification device of claim 17, wherein a first depth of the fourth test case is smaller than a second depth of the fifth test case.

19. The verification device of claim 17, wherein the plurality of second hierarchical level test cases further comprise a sixth test case, and the first test case is the father test case of the sixth test case, wherein a seventh test case of the plurality of test cases is an offspring test case of the sixth test case, wherein the test case generating circuit is further configured to copy the seventh test case to generate a second mix test case, to copy a plurality of second ancestor test cases tracing back from the seventh test case to the sixth test case to generate a plurality of sub second ancestor test cases, to create at least one fourth inheritance relation between the second mix test case and the plurality of sub second ancestor test cases according to at least one third inheritance relation trackback from the seventh test case to the sixth test case, and to assign a second root test case of the plurality of sub second ancestor test cases to inherit the fifth test case, wherein the second root test case is generated by copying the sixth test case, wherein the second mix test case is configured to mix verify the fourth test case, the fifth test case and the seventh test case.

20. The verification device of claim 12, wherein the test case generating circuit is further configured to generate the plurality of test cases and a plurality of inheritance relations between the plurality of test cases according to a test case configuration file.
